(19) United States
(12) Patent Application Publication
(10) Pub. No.: US 2025/0226282 A1
(43) Pub. Date: Jul. 10, 2025

(54) ELECTRONIC COMPONENT AND MANUFACTURING METHOD THEREOF

(71) Applicant: Taiwan Semiconductor Manufacturing Company, Ltd., Hsinchu (TW)

(72) Inventors: Kuang-Wei Yang, Hsinchu City (TW); Shao-Kuan Lee, Kaohsiung City (TW); Cheng-Chin Lee, Taipei City (TW); Hsin-Yen Huang, New Taipei City (TW); Hsiao-Kang Chang, Hsinchu City (TW)

(73) Assignee: Taiwan Semiconductor Manufacturing Company, Ltd., Hsinchu (TW)

(21) Appl. No.: 18/407,381

(22) Filed: Jan. 8, 2024

(51) Int. Cl. H01L 23/373; H01L 23/522; H01L 23/528

(52) U.S. Cl. CPC H01L 23/373; H01L 23/5226; H01L 23/5283

(57) ABSTRACT

An electronic device including a substrate, a first dielectric layer, a plurality of interconnects, a second dielectric layer, a plurality of electrically conductive vias, and an electronic device is provided. The first dielectric layer is disposed on the substrate. The interconnects are disposed on the substrate. The second dielectric layer is disposed on the first dielectric layer. The electrically conductive vias penetrate the second dielectric layer. The electronic device is disposed on the second dielectric layer and electrically connected to at least one of the interconnects through at least one of the electrically conductive vias. A thermal conductivity of the first dielectric layer, a thermal conductivity of the interconnects, a thermal conductivity of the second dielectric layer, or/and a thermal conductivity of the electrically conductive vias are larger than a thermal conductivity of cupper.

### BACKGROUND

The semiconductor integrated circuit (IC) industry has experienced a fast-paced growth. Technological advances in IC materials and design have produced generations of ICs where each generation has smaller and more complex circuits than the previous generation. The heat generated when the IC is operating may affect the quality. The quality of the IC may be improved through material selection or structural adjustments.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1H illustrate various cross-sectional views of some embodiments of a method of forming an electronic component.

FIG. 1I illustrates a portion of various cross-sectional view of some embodiments of an electronic component.

FIG. 1J illustrates a portion of stereo view of some embodiments of an electronic component.

FIG. 2 illustrates a various cross-sectional view of some embodiments of an electronic component.

FIG. 3 illustrates a various cross-sectional view of some embodiments of an electronic component.

FIG. 4 illustrates a various cross-sectional view of some embodiments of an electronic component.

FIG. 5 illustrates a flow diagram of some embodiments of a method of forming an electronic component.

### DETAILED DESCRIPTION

The following disclosure provides many different embodiments or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the component in use or operation in addition to the orientation depicted in the figures. The apparatus may be otherwise oriented (rotated 90 degrees or at other orientations) and the spatially relative descriptors used herein may likewise be interpreted accordingly.

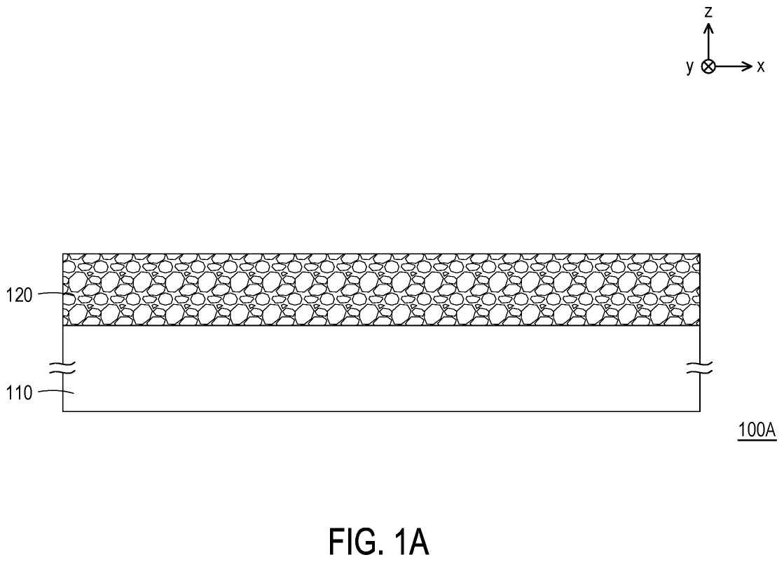

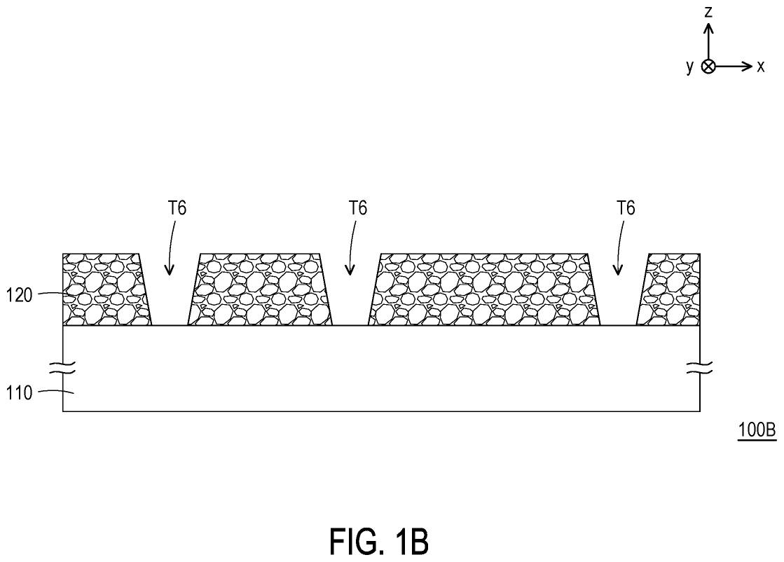

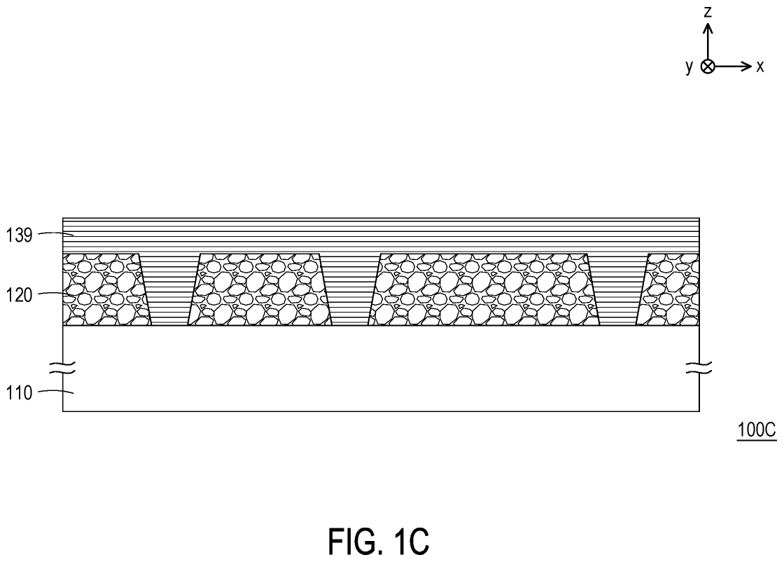

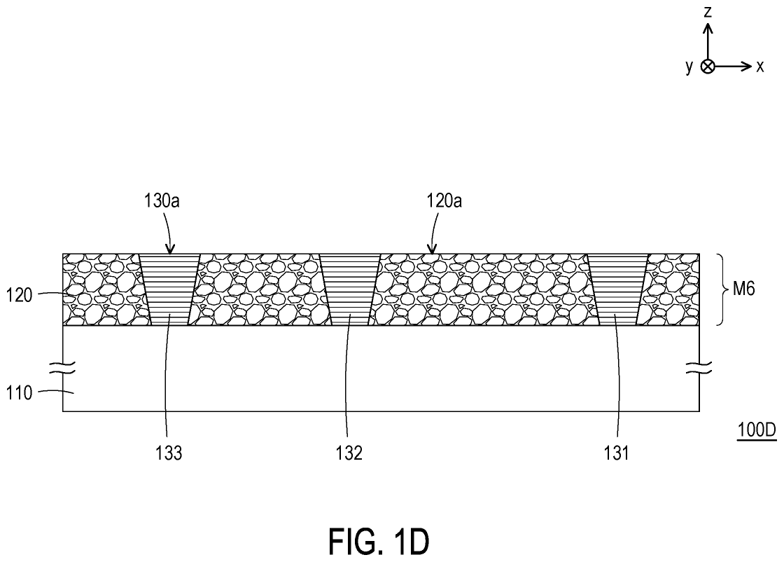

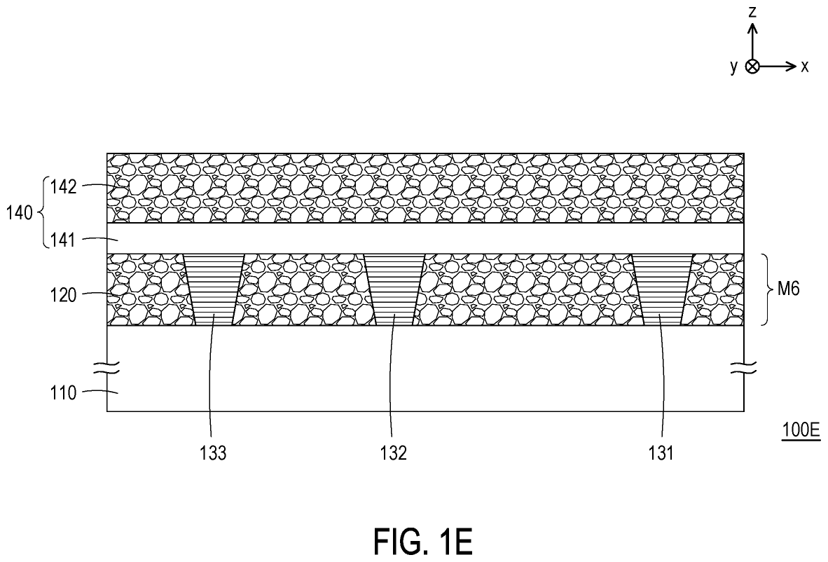

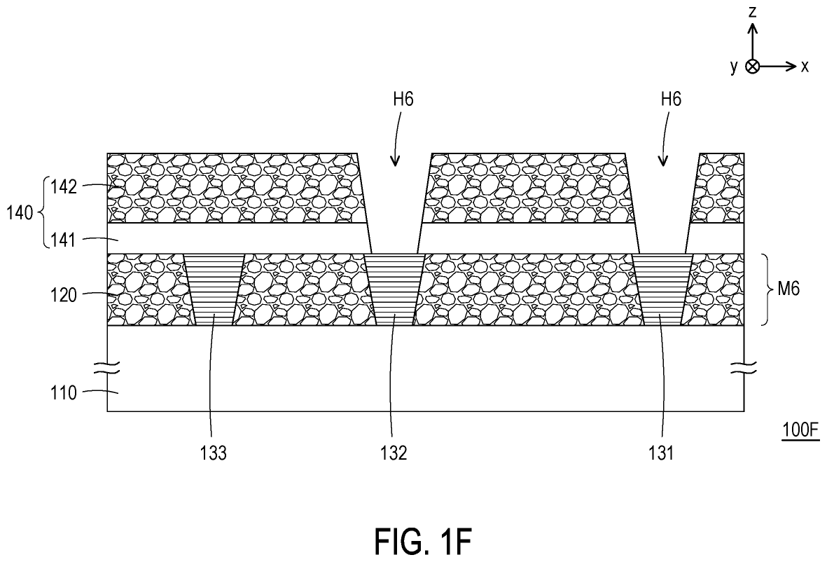

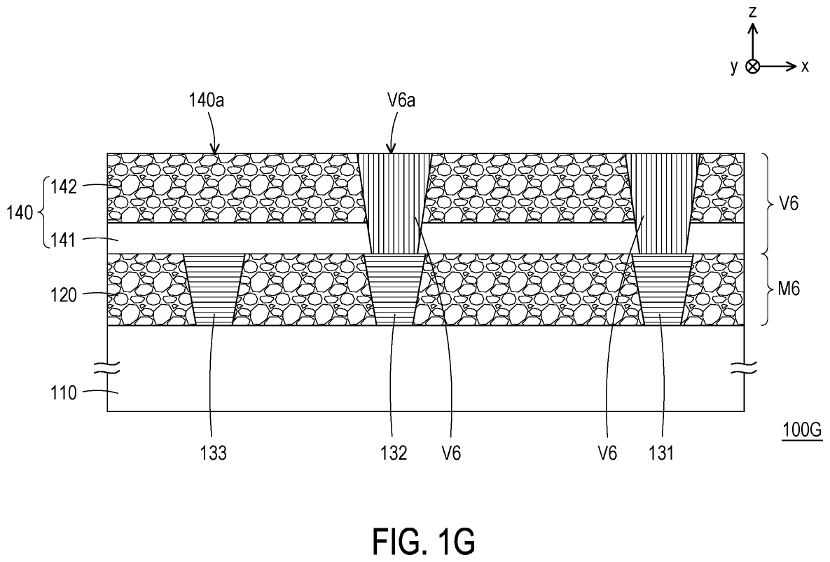

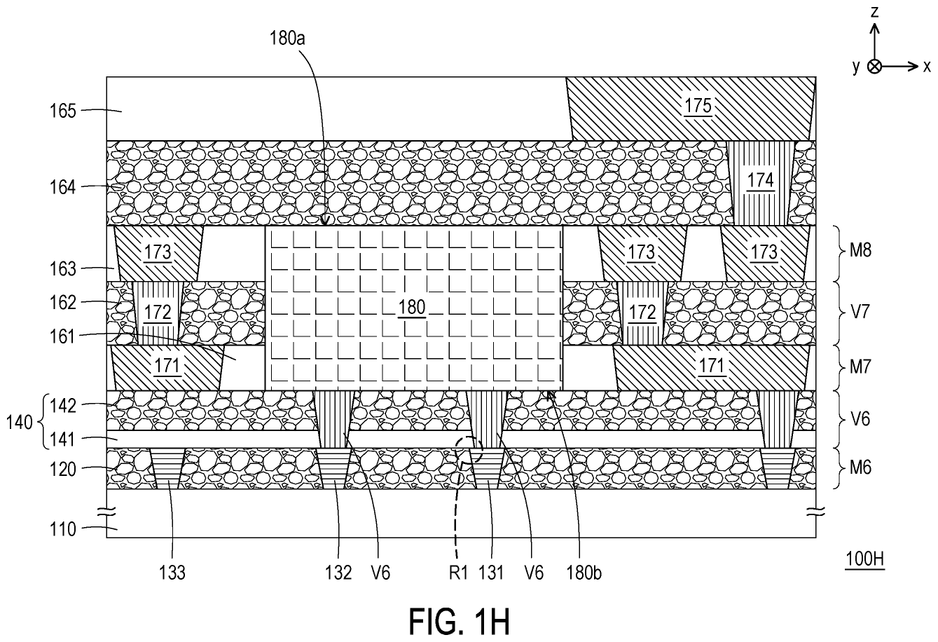

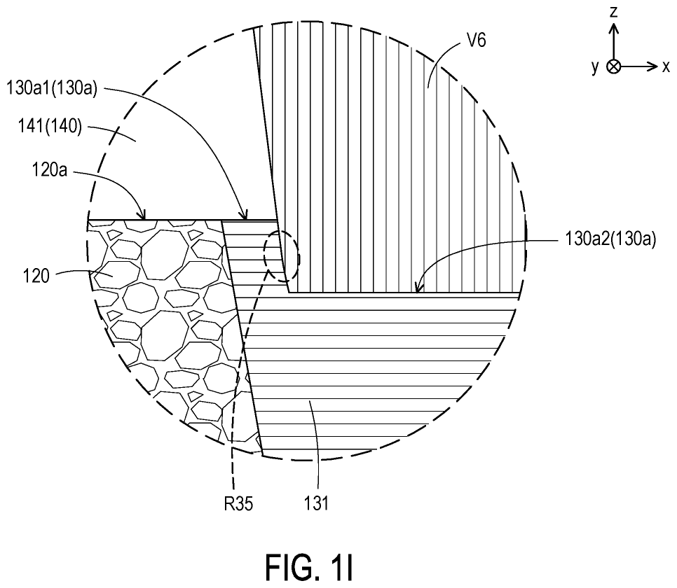

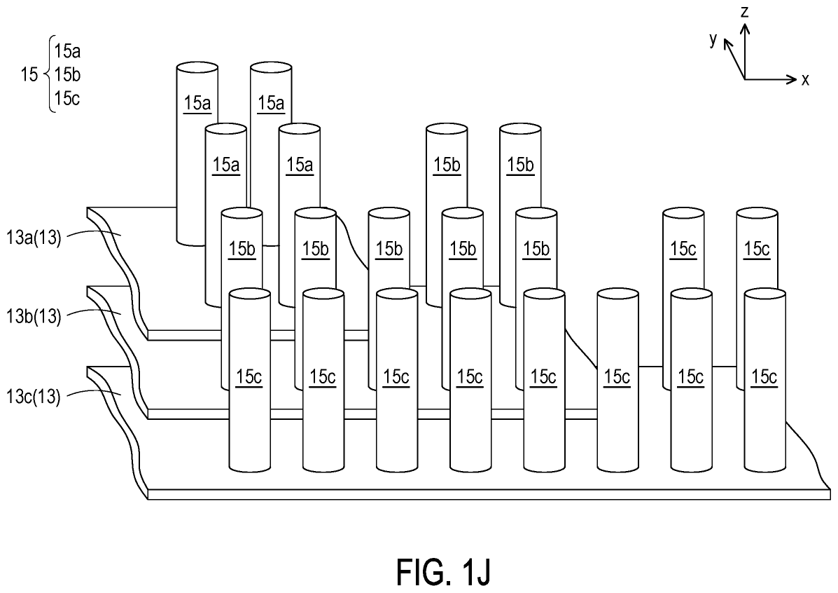

FIGS. 1A-1H illustrate various cross-sectional views of some embodiments of a method of forming an electronic component.

As shown in cross-sectional view of FIG. 1A, a structure 100A including a substrate 110 and a thermally conductive dielectric layer 120 disposed on the substrate is provided.

The substrate 110 may include a semiconductor substrate (e.g., a silicon (Si) substrate or a semiconductor wafer), a printed circuit board (e.g., an FR-4 printed circuit board), or a glass substrate, and the disclosure is not limited thereto. A structure including a semiconductor substrate may be referred as a semiconductor structure. Take a semiconductor wafer as an example, the substrate includes a crystalline silicon wafer. The substrate 110 may include various doped regions depending on design requirements (e.g., p-type substrate or n-type substrate). In some embodiments, the doped regions may be doped with p-type or n-type dopants. The doped regions may be doped with p-type dopants, such as boron or BF₂; n-type dopants, such as phosphorus or arsenic; and/or combinations thereof. The doped regions may be configured for n-type Fin-type Field Effect Transistors (FinFETs) and/or p-type FinFETs. A plurality of layers or regions disposed on the substrate (e.g., a semiconductor substrate) or embedded in the substrate may be considered a portion of the substrate 110. In some alternative embodiments, the substrate is made of some other suitable elemental semiconductor, such as diamond or germanium; a suitable compound semiconductor, such as gallium arsenide, silicon carbide, indium arsenide, or indium phosphide; or a suitable alloy semiconductor, such as silicon germanium carbide, gallium arsenic phosphide, or gallium indium phosphide. The substrate may further include interconnect structure formed over and electrically connected to the various doped regions. The interconnect structure may include a circuitry fabricated by front end of line (FEOL) or middle end of line (MEOL) processes. For example, an electrically conductive via may penetrate a dielectric region and electrically connect to a gate electrode, a source region, or drain region.

Referring to the FIG. 1A, a thermally conductive dielectric layer 120 is formed on the substrate 110. The thermally conductive dielectric layer 120 has high thermal conductivity and good electrical isolation and may be formed of aluminum nitride (e.g., AlN), aluminum oxide (e.g., Al₂O₃), silicon nitride (e.g., Si₃N₄), silicon carbide (e.g., SiC), carbon (e.g., such as diamond, or the like), boron nitride (e.g., BN, for example, hexagonal boron nitride (h-BN, graphitic BN)), beryllium oxide (e.g., BeO), magnesium oxide (e.g., MgO), another suitable material, or any combination of the foregoing.

In an embodiment, a thermal conductivity of the thermally conductive dielectric layer 120 is larger than a thermal conductivity of a commonly used electrically conductive metal material (e.g., aluminum (Al), cupper (Cu), or silver (Ag)). In an embodiment, a thermal conductivity of the thermally conductive dielectric layer 120 is larger than or substantially equal to 30 W/m-K, for example, 30 W/m-K to 3,000 W/m-K. In an alternative embodiment, a thermal conductivity of the thermally conductive dielectric layer 120 is substantially 500 W/m-K to 2,500 W/m-K.

In an embodiment, a thermally conductive dielectric layer 120 is or includes a diamond layer. A breakdown electric field of the diamond layer may be 5 MV/cm˜10 MV/cm approximately. A hardness of the diamond layer may larger than 50 GPa, for example, 70 GPa approximately.

A diamond layer may be formed by the following process. A surface treatment is optionally provided on a surface of an object (e.g., the substrate 110, or a layer disposed on the substrate 110). The aforementioned surface treatment may include a surface roughening treatment by a corresponding acid and/or base. A seeding treatment is provided by forming a diamond-precursor on the surface of the object, and then the object with the diamond-precursor formed thereon is cleaned in an appropriate solvent (e.g., methanol, ethanol, isopropyl alcohol, acetone, or a co-solvent thereof). The aforementioned diamond-precursor may include a seed layer formed by an appropriate seeding process (e.g., deposition, spin-coating, ultrasonic scratch, electrostatic or bias enhanced nucleation) with a carbon-containing reactant (e.g., methane (CH₄), ethane (C₂H₆), ethylene (C₂H₄), acetylene (C₂H₂), or a mixture thereof) or a seed powder (e.g., graphite powder, adamantane powder, diamond powder, or a mixture thereof). The particle size of the aforementioned seed powder may be small than or substantially equal to 1 micrometer (μm), for example, having an average grain size from 0.05 μm to 0.5 μm. Then, a deposition process (e.g., a Microwave Plasma Enhanced Chemical Vapor Deposition (MWCVD) or a Hot-Filament Chemical Vapor Deposition (HFCVD), but not limited) is performed to the object subjected to the aforementioned seeding treatment. A process gas (including a reactant gas, a carrier gas, a doping gas, or a buffer gas) for the aforementioned deposition process may include a carbon-containing gas (e.g., methane (CH₄), ethane (C₂H₆), ethylene (C₂H₄), acetylene (C₂H₂), or a mixture thereof), hydrogen (H₂), oxygen (O₂), carbon dioxide (CO₂), nitrogen (N₂), ammonia (NH₃), argon (Ar), helium (He), or a mixture thereof. A process temperature for the aforementioned deposition process may be lower than 500 degrees Celsius (° C.), for example, lower than or substantially equal to 450° C.

As shown in cross-sectional view of FIG. 1B, a structure 100B including at least on trench T6 is formed. The trench T6 is formed to penetrate through the thermally conductive dielectric layer 120. The trench T6 may be formed by a suitable removal process (e.g., a photolithography followed by an etching process). The trench T6 may expose a portion of an electrical conductor (e.g., an electrically conductive via, not shown in FIG. 1B) under the thermally conductive dielectric layer 120. Two trenches T6 that are not connected seemingly in a cross-sectional view may be connected essentially in other cross-sectional view.

As shown in cross-sectional view of FIG. 1C, a structure 100C including a thermally and electrically conductive material 139 is formed. The thermally and electrically conductive material 139 is formed on the thermally conductive dielectric layer 120 and filling into the trenches T6. In an embodiment, the portion of the thermally and electrically conductive material 139 filling into the trench may be in contact with a portion of an electrical conductor exposed by the corresponding trench T6.

The thermally and electrically conductive material 139 has high thermal conductivity and good electrical conductivity. In an embodiment, a thermal conductivity of the thermally and electrically conductive material 139 is larger than a thermal conductivity of a commonly used conductive metal material (e.g., aluminum (Al), cupper (Cu), or silver (Ag)). In an embodiment, a thermal conductivity of the thermally and electrically conductive material 139 is larger than or substantially equal to 1,000 W/m-K, for example, larger than or substantially equal to 4,000 W/m-K. In an embodiment, the thermally and electrically conductive material 139 includes an electrically conductive 2D material, for example, carbon-based electrically conductive 2D material, transition metal dichalcogenides (TMDs or TMDCs). The transition metal dichalcogenide includes, for example, molybdenum sulfide (MoS₂), tantalum sulfide (TaS₂), hafnium sulfide (HfS₂), hafnium selenide (HfSe₂), tungsten selenide (WSe₂), or a ternary compound thereof (e.g., HfS₂₍₁₋ₓ₎Se₂ₓ). The carbon-based electrically conductive 2D material includes, for example, one or more graphite layers, a stacked graphene layer (e.g., a stacked structure of a plurality of single graphene layers), or any combination o or stack of the foregoing. The graphite or graphene layer may be undoped or doped. For example, the graphene layer may be intercalated graphene or modified graphene. The electrical conductivity of the stacked graphene layer may be adjusted (e.g., enhanced) by appropriate doped metal elements and/or metal ions. For example, the Fermi level of the stacked graphene layer may be adjusted by dopants. Doped metals/ions may include appropriate transition metals/ions (e.g., iron/iron ion/Fe/Fe²⁺/Fe³⁺; copper/copper ion/Cu/Cu⁺/Cu²⁺; nickel/nickel ion/Ni/Ni⁺/Ni²⁺/Ni³⁺/Ni⁴⁺), alkaline earth ions (e.g., calcium ion/Ca²⁺), or corresponding anions.

A stacked graphene layer may be formed by the following process. A seeding or catalyst treatment is optionally provided by forming a seed or catalyst layer on the surface of the object (e.g., the substrate 110 with the thermally conductive dielectric layer 120 disposed thereon). The aforementioned seed or catalyst layer may be a metal layer (e.g., a Cu layer, or a Ni layer) with a thickness of less than or substantially equal to 500 nm (e.g., 10 nm˜300 nm) formed by an appropriate deposition process (e.g., physical vapor deposition (PVD), chemical vapor deposition (CVD), atomic layer deposition (ALD), or the like). A deposition process (e.g., a Plasma-Enhanced Chemical Vapor Deposition (PECVD)) is performed to the object (e.g., the substrate 110 with the thermally conductive dielectric layer 120 disposed thereon, or the substrate 110 with the seed or catalyst layer disposed thereon) to form the stacked graphene layer. A process reagent (e.g., a reactant gas, a carrier gas, a doping gas, or a buffer gas) for the aforementioned deposition process may include a carbon-containing gas (e.g., methane (CH₄), ethane (C₂H₆), ethylene (C₂H₄), acetylene (C₂H₂), methanol (MeOH), benzene (C₆H₆), or a mixture thereof), oxygen (O₂), carbon dioxide (CO₂), nitrogen (N₂), ammonia (NH₃), argon (Ar), helium (He), or a mixture thereof. A process temperature for the aforementioned deposition process may be lower than 500 degrees Celsius (° C.), for example, lower than or substantially equal to 450° C. Corresponding elements (e.g., Cu and/or Ni) in the seed or catalyst layer may diffuse into the stacked graphene layer, resulting in the stacked graphene layer having corresponding doping.

As shown in cross-sectional view of FIG. 1D, a structure 100D including at least on interconnect is formed. At least a portion of the thermally and electrically conductive material 139 (as shown in FIG. 1C) is removed to form the interconnects 131, 132, 133. Two interconnects that are not connected seemingly in a cross-sectional view may be connected essentially in other cross-sectional view. Top surfaces 130a of the interconnects 131, 132, 133 and a top surface 120a of the thermally conductive dielectric layer 120 may be substantially coplanar, and the top surfaces 130a of the interconnect 131, 132, 133 and the top surface 120a of the thermally conductive dielectric layer 120 may be treated by a planarization process (e.g., a chemical mechanical planarization (CMP) process).

As shown in cross-sectional view of FIG. 1E, a structure 100E including a dielectric layer 140 is formed. The dielectric layer 140 may include a first dielectric layer 141 and a second dielectric layer 142.

The first dielectric layer 141 may include an etching-stop layer (ESL). A material of the etching-stop layer may include silicon oxycarbide (SiOC), silicon oxynitride (SiON), silicon carbide nitride (SiCN), silicon oxycarbonitride (SiOCN), aluminum oxide (AlO), aluminum nitride (AlN), aluminum oxycarbide (AlOC), aluminum oxynitride (AlON), and/or combinations thereof. The first dielectric layer 141 may be formed by an appropriate process (e.g., a CVD, ALD, a molecular layer deposition (MLD), a spin-on process, or the like).

A formation process and/or a material of the second dielectric layer 142 may be the same or similar to the formation process and/or the material of the aforementioned thermally conductive dielectric layer 120 as shown in FIG. 1A.

As shown in cross-sectional view of FIG. 1F, a structure 100F including at least on hole H6 is formed. The hole H6 is formed to penetrate through the dielectric layer 140. The hole H6 may be form by a suitable removal process (e.g., a photolithography followed by an etching process). The hole H6 may expose a portion of an electrical conductor (e.g., the interconnects 131, 132) under the dielectric layer 140.

In an embodiment, during the aforementioned removal process, a portion of the interconnect (e.g., the interconnect 131 and/or 132) is removed. For example, the top of the interconnect (e.g., the interconnect 131 and/or 132) has a recess corresponding to the bottom of the hole H6. The side wall of the recess is beveled substantially. That is, the side wall of the recess is substantially a sloped line in a cross-sectional view.

As shown in cross-sectional view of FIG. 1G, a structure 100G including at least one electrically conductive via V6 is formed. The electrically conductive via V6 may be formed by filling electrically conductive material into the hole H6 (as shown in FIG. 1F). The electrically conductive material for forming the electrically conductive via V6 has high thermal conductivity and good electrical conductivity. In an embodiment, a thermal conductivity of the electrically conductive material for forming the electrically conductive via V6 is larger than a thermal conductivity of a commonly used electrically conductive metal material (e.g., aluminum (Al), cupper (Cu), or silver (Ag)). In an embodiment, a thermal conductivity of the electrically conductive material for forming the electrically conductive via V6 is larger than or substantially equal to 1,000 W/m-K, for example, larger than or substantially equal to 4,000 W/m-K.

In an embodiment, the electrically conductive material for forming the electrically conductive via V6 includes carbon-based electrically conductive filler such as carbon nanotubes (CNTs), carbon nanofibers, or carbon fibers. The carbon-based electrically conductive filler (e.g., CNTs) may be formed by an appropriate process, such as a CVD process, a physical vapor deposition (PVD) process, or an atomic layer deposition (ALD) process. A process reagent (e.g., a reactant gas, a carrier gas, a doping gas, or a buffer gas) for the aforementioned deposition process may include a carbon-containing gas (e.g., methane (CH₄), ethane (C₂H₆), ethylene (C₂H₄), acetylene (C₂H₂), methanol (MeOH), benzene (C₆H₆), or a mixture thereof), oxygen (O₂), carbon dioxide (CO₂), nitrogen (N₂), ammonia (NH₃), argon (Ar), helium (He), or a mixture thereof. The hole (e.g., the hole H₆ as shown in FIG. 1F) may be filled with a plurality of CNTs that extend through the thickness of the dielectric layer 140 (e.g., along to the z-direction). In an embodiment, the CNTs may be formed over an electrically conductive feature, such as a catalyst layer (not shown) within the hole. In an embodiment, a group of the CNTs vertically overlapping with a corresponding interconnect (the interconnects 131, 132) is electrically coupled therewith. In an embodiment, after filling electrically conductive material into the hole (e.g., the hole H6 as shown in FIG. 1F), a planarization process (e.g., a CMP process) is performed. In an embodiment, top surfaces V6a of the electrically conductive vias V6 and the top surface 140a of the dielectric layer 140 may be substantially coplanar. In an alternative embodiment, a top surface V6a of the electrically conductive via V6 may be slightly concave than the top surface 140a of the dielectric layer 140.

In an embodiment, interspaces between the plurality of CNTs are filled with electrically conductive material. The aforementioned electrically conductive material may include a metal, such as titanium (Ti), cobalt (Co), nickel (Ni), platinum (Pt), erbium (Er), palladium (Pa), intermetallic compound (IMC) or alloy thereof. The aforementioned electrically conductive material may be formed by an appropriate, such a CVD process, a metal organic CVD (MOCVD) process, a PVD process, or an ALD process. The aforementioned electrically conductive material may wrap around and/or encapsulate the CNTs. In an embodiment, the CNTs act as electrical channels for transmission of charges, and the aforementioned electrically conductive material acts as a support for supporting the CNTs within the hole. In an embodiment, the aforementioned electrically conductive material further act as electrical channels.

In an alternative embodiment, the CNTs are electrically conductive and include hollow tubes. In an alternative embodiment, interspaces between the plurality of CNTs are unfilled.

A patterned electrically conductive layer for being formed the corresponding interconnects (e.g., interconnects 131, 132, 133) may be referred as an Mi layer, and a patterned electrically conductive layer for being formed the corresponding electrically conductive vias (e.g., electrically conductive vias V6) may be referred as a Vj layer, wherein “i” and “j” are natural numbers or positive integers. For example, a portion of the patterned electrically conductive layer for being formed the corresponding interconnects 131, 132, 133 is referred as an M6 layer. For example, a portion of the patterned electrically conductive layer for being formed the corresponding electrically conductive vias V6 is referred as an V6 layer.

As shown in cross-sectional view of FIG. 1H, a structure 100H including an electronic device 180 is formed. The electronic device 180 may be or include a passive device. The electronic device 180 may be used as a bandgap voltage reference, a proportion operational amplifier, a voltage divider, or a bus terminator in an analog and mixed signal circuit or a specific System on Chip (SoC) application. The electronic device 180 may have a higher resistance and may be referred as a high R resistor. In an embodiment, the electronic device 180 is formed by an appropriate semiconductor process. In an alternative embodiment, the electronic device 180 is a pre-formed device.

The electronic device 180 may be electrically connected to one or more corresponding interconnects 131, 132 by one or more corresponding electrically conductive vias V6. The materials of the electrically conductive vias V6 and/or the interconnects 131, 132 may include corresponding high thermally and electrically conductive materials, therefore the heat generated may be transferred to the electrically conductive vias V6 and/or the interconnects 131, 132 easily and quickly when the electronic device 180 is operating.

Referring to the FIG. 1H, one or more dielectric layer (e.g., dielectric layers 161, 162, 163, 164, 165) and one or more patterned electrically conductive layer (e.g., electrically conductive layers 171, 172, 173, 174, 175) are formed on the substrate 110 by an appropriate process. In an embodiment, a material of the aforementioned dielectric layer includes, for example, silicon oxide (SiO), silicon carbide (SiC), silicon nitride (SiN), silicon oxynitride (SiNO), silicon carbon nitride (SiCN), nitride-doped silicon oxide (SiCON), aluminum nitride (AlN), aluminum oxynitride (AlON), aluminum oxide (AlO), and/or combinations thereof. In an alternative embodiment, a material of the aforementioned dielectric layer is the same or similar to the material of the thermally conductive dielectric layer 120, and the dielectric layer has the same or similar formation method as mentioned above. In an embodiment, a material of the aforementioned patterned electrically conductive layer includes, for example, aluminum (Al), cobalt (Co), copper (Cu), iron (Fe), indium (In), iridium (Ir), manganese (Mn), molybdenum (Mo), nickel (Ni), osmium (Os), ruthenium (Ru), tantalum (Ta), titanium (Ti), tungsten (W), zinc (Zn), zirconium (Zr), an alloy thereof, and/or a eutectic thereof. In an alternative embodiment, a material of the aforementioned patterned electrically conductive layer is the same or similar to the material of the thermally and electrically conductive material 139, and the patterned electrically conductive layer has the same or similar formation method as mentioned above.

The structure 100H as shown in FIG. 1H may be a portion of an electronic component. That is, FIG. 1H may illustrate a portion cross-sectional view of some embodiments of an electronic component. FIG. 1I may illustrate a portion of various top view of some embodiments of an electronic component. For example, FIG. 1I may correspond to the region R1 as shown in FIG. 1H. FIG. 1J may illustrate a portion of stereo view of some embodiments of an electronic component. For example, FIG. 1J may correspond to the region R35 as shown in FIG. 1I.

As sown in FIGS. 1H, 1I and/or 1J, the electronic component may include a substrate 110, a first dielectric layer 120, a plurality of interconnects 131, 132, 133, a second dielectric layer 140, a plurality of electrically conductive vias V6, and an electronic device 180. The first dielectric layer 120 is disposed on the substrate 110. The interconnects 131, 132, 133 are disposed on the substrate 110. The second dielectric layer 140 is disposed on the first dielectric layer 120. The electrically conductive vias V6 penetrate the second dielectric layer 140. The electronic device 180 is disposed on the second dielectric layer 140. The electronic device 180 is electrically connected to at least one corresponding interconnect (e.g., interconnects 131, 132) through at least one corresponding electrically conductive via V6. A thermal conductivity of the material for forming the first dielectric layer 120, a thermal conductivity of the material for forming the interconnects 131, 132, 133, a thermal conductivity of the material for forming the second dielectric layer 140, and/or a thermal conductivity of the material for forming the electrically conductive vias V6 is/are larger than a thermal conductivity of a commonly used conductive metal material (e.g., aluminum (Al), cupper (Cu), or silver (Ag)).

In an embodiment, the top of the interconnect (e.g., the interconnect 131 and/or 132) has a recess corresponding to the bottom of the electrically conductive via V6. That is, a portion of the electrically conductive via V6 may embedded in the corresponding interconnect (e.g., the interconnect 131 and/or 132). For example, the top surface 130a of the interconnect (e.g., the interconnect 131 and/or 132) being in contacted with the electrically conductive via V6 has a recess region 130a2 and a peripheral area 130al surrounding the recessed area 130a2. There is a vertical difference between the recess region 130a2 and the peripheral area 130al in a vertical direction (e.g., along to the z-direction). In the vertical direction, a vertical difference between the recess region 130a2 and the top surface 120a of the thermally conductive dielectric layer 120 is larger than a vertical difference between the peripheral area 130al and the top surface 120a of the thermally conductive dielectric layer 120. In an embodiment, the peripheral area 130al and the top surface 120a of the thermally conductive dielectric layer 120 are substantially coplanar.

In an embodiment, corresponding side walls of the recess of the interconnect (e.g., the interconnect 131 and/or 132) and the embedded portion of the electrically conductive via V6 beveled substantially. That is, corresponding side walls of the recess of the interconnect (e.g., the interconnect 131 and/or 132) and the embedded portion of the electrically conductive via V6 are substantially a sloped line in a cross-sectional view, for example, the region R35 as shown in FIG. 1I.

In an embodiment, a material for forming the interconnect (e.g., the interconnect 131 and/or 132) includes electrically conductive 2D material (e.g., carbon-based electrically conductive 2D material) having a plurality of electrically conductive single layers 13, and a material for forming the electrically conductive via V6 includes carbon-based electrically conductive filler (e.g., carbon nanotubes (CNTs), carbon nanofibers, or carbon fibers) having a plurality of electrically conductive single columns 15. An electrical resistance (e.g., electrical sheet resistance) of electrically conductive 2D material (e.g., graphene) may be lower in directions parallel to a plane (e.g., directions parallel to x-y plane) in which atoms of one single layer are organized (e.g., parallel to a major surface of a graphene sheet), and an electrical resistance (e.g., electrical sheet resistance) of the aforementioned electrically conductive 2D material may be higher in a direction perpendicular to the aforementioned plane (e.g., the z-direction). Additionally, a current flow direction of carbon-based electrically conductive filler (e.g., carbon nanotubes (CNTs)) is substantially along the extension direction (e.g., the z-direction) of the single column. As such, as shown in FIG. 1J corresponding to the region R35 in FIG. 1I, in the structure with the aforementioned beveled side wall, a portion of the electrically conductive single layers 13 and a portion of the electrically conductive single columns 15 may form a corresponding electrically conductive group. For example, the electrically conductive single layer 13a and the electrically conductive single columns 15a may form an electrically conductive group, the electrically conductive single layer 13b and the electrically conductive single columns 15b may form another electrically conductive group, and the electrically conductive single layer 13c and the electrically conductive single columns 15c may form another one electrically conductive group. In this way, the electrical conductivity between the interconnect (e.g., the interconnect 131 and/or 132) forming by electrically conductive 2D material and the electrically conductive via V6 forming by carbon-based electrically conductive filler may be improved. In an embodiment, electrically conductive material wrapping around and/or encapsulating the carbon-based electrically conductive filler acts as a support and further enhance the electrical conductivity.

In an embodiment, the electronic component may further include one or more dielectric layer (e.g., dielectric layers 161, 162, 163, 164, 165) and one or more patterned electrically conductive layers (e.g., electrically conductive layers 171, 172, 173, 174, 175). The patterned electrically conductive layer 171 and the patterned electrically conductive layer 173 including corresponding interconnects may be referred as an M7 layer and an M8 layer respectively. The patterned electrically conductive layer 172 including corresponding electrically conductive vias may be referred as a V7 layer. The topmost patterned electrically conductive layer 175 may include one or more die pads. The die pad may be a copper pad or an aluminum pad. The topmost dielectric layer 165 may be referred as a passivation layer.

In an embodiment, a thickness of the electronic device 180 is thicker than thickness of the one or more dielectric layers and/or the one or more patterned electrically conductive layers. For example, the thickness of the electronic device 180 is thicker than the thickness of the patterned electrically conductive layers 171, 172, 173, and the thickness of the dielectric layers 161, 162, 163. In an embodiment, the patterned electrically conductive layers 171, 172, 173 and the dielectric layers 161, 162, 163 are disposed between two planes where the top surface and bottom surfaces 180a, 180b of the electronic device 180 are located respectively.

In an embodiment, at least one dielectric layer (e.g., the dielectric layer 162) disposed between two planes where the top surface and bottom surfaces 180a, 180b is in contacted with the electronic device 180 and has a thermal conductivity which is larger than a thermal conductivity of a commonly used electrically conductive metal material (e.g., aluminum (Al), cupper (Cu), or silver (Ag)). As such, the heat dissipation efficiency may be improved.

In an embodiment, at least one dielectric layer (e.g., the dielectric layers 142, 164) in contacted with the top surface and/or bottom surfaces 180a, 180b of the electronic device 180 has a thermal conductivity which is larger than a thermal conductivity of a commonly used electrically conductive metal material. As such, the heat dissipation efficiency may be improved.

In an embodiment, an electrically conductor (e.g., electrically conductive vias or interconnects) penetrating or within the dielectric layer (e.g., the dielectric layer 120, 142, 162, 164) having a larger thermal conductivity has a thermal conductivity which is larger than a thermal conductivity of a commonly used electrically conductive metal material. As such, the heat dissipation efficiency may be improved.

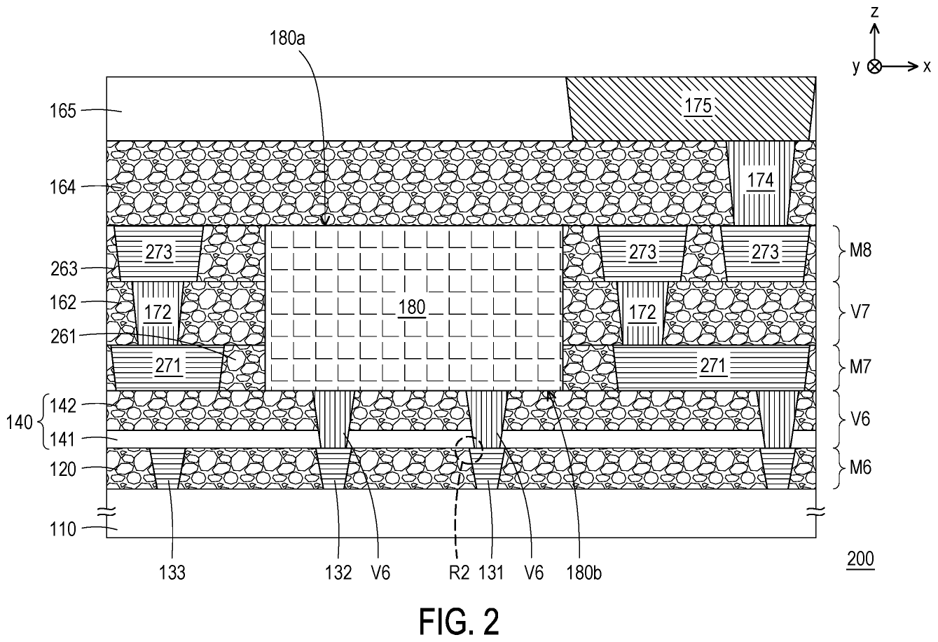

FIG. 2 illustrates various cross-sectional views of some embodiments of an electronic component. Elements, devices, or components having same or similar functions may be denoted by same or similar referential numbers. Descriptions of said elements, devices, or components may be omitted for brevity.

The structure 200 as shown in FIG. 2 may be a portion of an electronic component. The structure 200 as shown in FIG. 2 may be similar to the structure 100H as shown in FIG. 1H. For example, FIG. 1I may correspond to the region R2 as shown in FIG. 2, and as shown in FIGS. 2, 1I and/or 1J, the electronic component includes a substrate 110, a first dielectric layer 120, a plurality of interconnects 131, 132, 133, a second dielectric layer 140, a plurality of electrically conductive vias V6, and an electronic device 180.

In an embodiment, the electronic component may further include one or more dielectric layer (e.g., dielectric layers 261, 162, 263, 164, 165) and one or more patterned electrically conductive layers (e.g., electrically conductive layers 271, 172, 273, 174, 175). The patterned electrically conductive layer 271 and the patterned electrically conductive layer 273 including corresponding interconnects may be referred as an M7 layer and an M8 layer respectively.

In an embodiment, the thickness of the electronic device 180 is thicker than the thickness of the patterned electrically conductive layers 271, 172, 273, and the thickness of the dielectric layers 261, 162, 263. In an embodiment, the patterned electrically conductive layers 271, 172, 273 and the dielectric layers 261, 162, 263 are disposed between two planes where the top surface and bottom surfaces 180a, 180b of the electronic device 180 are located respectively.

In an embodiment, all dielectric layers (e.g., dielectric layers 142, 261, 162, 263, and 164) in contacted with the electronic device 180 and has a thermal conductivity which is larger than a thermal conductivity of a commonly used electrically conductive metal material. As such, the heat dissipation efficiency may be improved.

In an embodiment, an electrical conductor (e.g., electrically conductive vias or interconnects) penetrating or within the dielectric layer (e.g., the dielectric layer 120, 142, 261, 162, 263, 164) having a larger thermal conductivity has a thermal conductivity which is larger than a thermal conductivity of a commonly used electrically conductive metal material. As such, the heat dissipation efficiency may be improved.

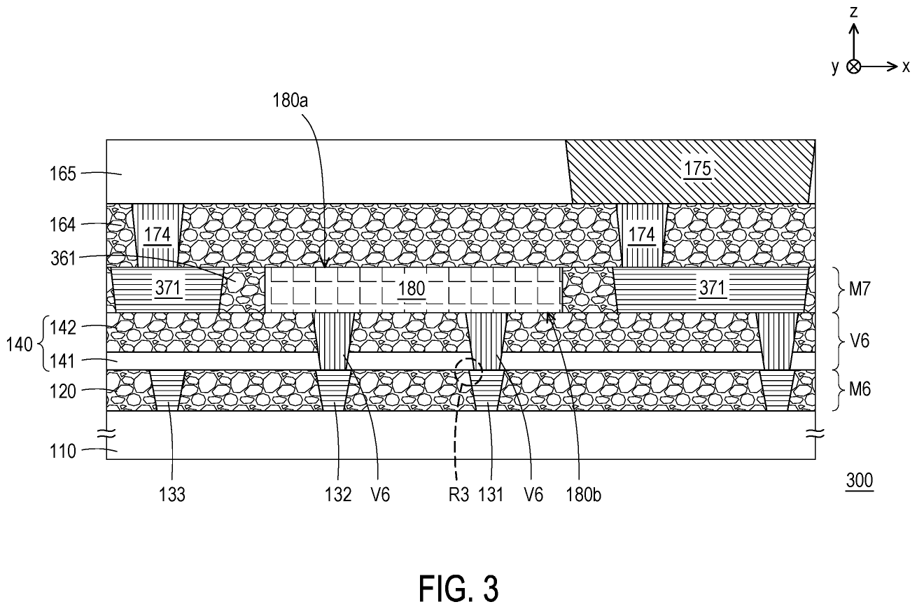

FIG. 3 illustrates various cross-sectional views of some embodiments of an electronic component. Elements, devices, or components having same or similar functions may be denoted by same or similar referential numbers. Descriptions of said elements, devices, or components may be omitted for brevity.

The structure 300 as shown in FIG. 3 may be a portion of an electronic component. The structure 300 as shown in FIG. 3 may be similar to the structure 100H as shown in FIG. 1H or the structure 200 as shown in FIG. 2. For example, FIG. 1I may correspond to the region R3 as shown in FIG. 3, and as shown in FIGS. 3, 1I and/or 1J, the electronic component includes a substrate 110, a first dielectric layer 120, a plurality of interconnects 131, 132, 133, a second dielectric layer 140, a plurality of electrically conductive vias V6, and an electronic device 180.

In an embodiment, the electronic component may further include one or more dielectric layer (e.g., dielectric layers 361, 164, 165) and one or more patterned electrically conductive layers (e.g., electrically conductive layers 271, 174, 175).

In an embodiment, the thickness of the electronic device 180 is substantially equal to the thickness of the patterned electrically conductive layer 271, and the thickness of the dielectric layer 361. In an embodiment, the top surface and bottom surfaces of the patterned electrically conductive layer 271 and the dielectric layers 361 and the top surface and bottom surfaces 180a, 180b of the electronic device 180 are substantially coplanar.

In an embodiment, all dielectric layers (e.g., dielectric layers 142, 361, and 164) in contacted with the electronic device 180 and has a thermal conductivity which is larger than a thermal conductivity of a commonly used electrically conductive metal material. As such, the heat dissipation efficiency may be improved.

In an embodiment, an electrical conductor (e.g., electrically conductive vias or interconnects) penetrating or within the dielectric layer (e.g., the dielectric layer 120, 142, 361, 164) having a larger thermal conductivity has a thermal conductivity which is larger than a thermal conductivity of a commonly used electrically conductive metal material. As such, the heat dissipation efficiency may be improved.

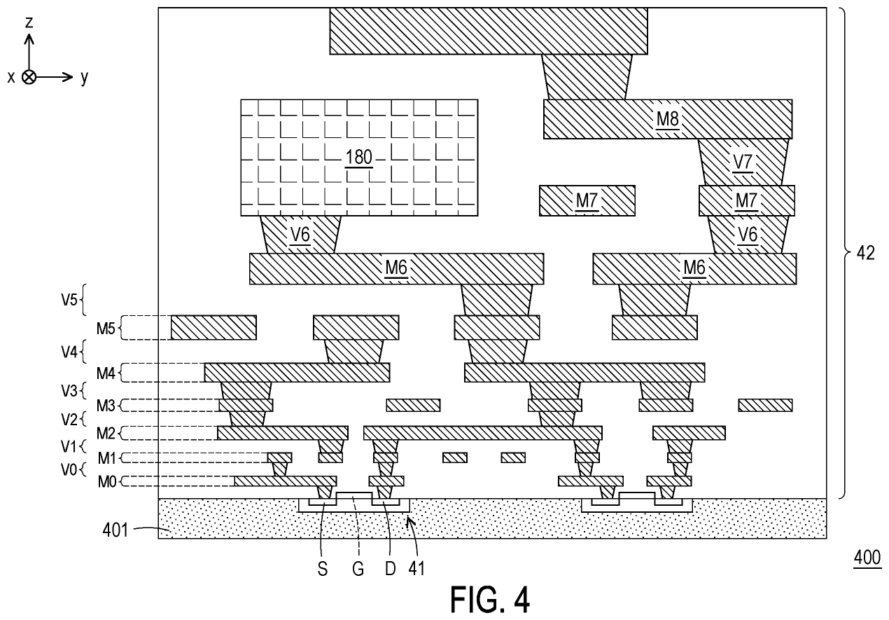

FIG. 4 illustrate an exemplary cross-sectional view of a die (e.g., a kind of electronic component) 400. The die 400 may include a semiconductor substrate 401, an active device (e.g., a transistor), a passive device (e.g., a resistor, a capacitor, or an inductance), and/or an interconnect structure. The device may be formed using front-end of line (FEOL) fabrication techniques. The interconnect structure may be formed using back-end of line (BEOL) fabrication techniques and may be electrically coupled to a corresponding device. The die 400 as shown in FIG. 4 exemplarily illustrate a corresponding active device 41 and a corresponding interconnect structure 42. The die 400 may be a dynamic random access memory (DRAM) die, a static random access memory (SRAM) die or a high bandwidth memory (HBM) die, an application-specific integrated circuit (ASIC) die, an application processor (AP) die, a system on chip (SoC) die or a high performance computing (HPC) die, but the disclosure is not limited thereto. The active device 41 and/or the interconnect structure 42 are exemplary shown in FIG. 4, the formations or types of the active device 41 and/or the interconnect structure 42 are not limited in the disclosure.

The interconnect structure 42 may include a plurality interconnect layers (e.g., an M0 layer, an M1 layer, . . . or an Mi layer). Each interconnect layer may include corresponding interconnects. Corresponding interconnects in adjacent interconnect layers extend in different directions. For example, interconnects (e.g., interconnects 131, 132, 133 as shown in FIGS. 1H, 2, and 3) in the M6 layer extend along the y-direction, and interconnects in the M5 and M7 layers extend along the x-direction. Corresponding interconnects in adjacent interconnect layers are electrically connected through corresponding electrically conductive vias in the via layer (e.g., a V0 layer, a V1 layer, a V2 layer, . . . or a Vi-1 layer) therebetween. A material of the M0 layer, the V0 layer, and/or the M1 layer may include Copper (Cu), Cobalt (Co), Ruthenium (Ru), Molybdenum (Mo), Chromium (Cr), Tungsten (W), Manganese (Mn), Rhodium (Rh), Iridium (Ir), Nickel (Ni), Palladium (Pd), Platinum (Pt), Silver (Ag), Gold (Au), Aluminum (Al), Tantalum (Ta), Titanium (Ti) or other metal nitride (e.g., titanium nitride (TiN), tantalum nitride (TaN)). A thickness of the M0 layer, the V0 layer, and/or the M1 layer may about 50 Å to 500 Å.

The topmost interconnect layer (e.g., the electrically conductive layer 175 as shown in FIGS. 1H, 2, and 3) in the interconnect structure 42 may include a plurality of die pads. The die pad may be a signal pad (e.g., an I/O pad) or a ground pad. A corresponding interconnect in the bottommost interconnect layer (e.g., the M0 layer) in the interconnect structure 42 is electrically connected a corresponding region of the device (e.g., the source S, the drain D, or the gate G, but the disclosure is not limited thereto) by one or more electrical conductors (e.g., corresponding electrically conductive vias).

Referring to FIG. 4 and the aforementioned figures, the structures 100H, 200, 300 of the aforementioned embodiments may be a portion of the die 400. Additionally, for simplicity of illustration, corresponding dielectric layers (e.g., the dielectric layers 120, 140, 164) are omitted in the FIG. 4.

In an embodiment, the heat generated by the electronic device 180 is greater than the heat generated by any interconnect in the interconnect structure 42 when the die (e.g., a kind of electronic component) 400 is operating.

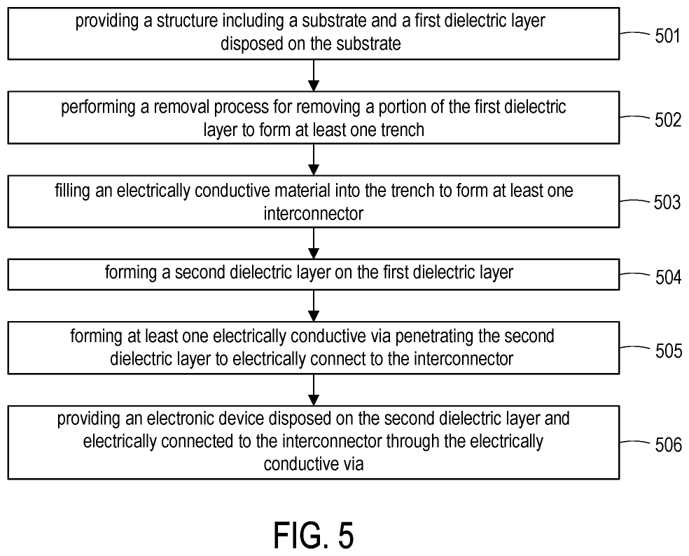

FIG. 5 illustrates a flow diagram of some embodiments of a method of forming an electronic component.

At act 501, a structure including a substrate and a first dielectric layer disposed on the substrate is provided. FIG. 1A illustrates a cross-sectional view corresponding to various embodiments of act 501. A thermal conductivity of the first dielectric layer may be larger than a thermal conductivity of a commonly used electrically conductive metal material (e.g., aluminum (Al), cupper (Cu), or silver (Ag)).

At act 502, a removal process is performed for removing a portion of the first dielectric layer to form at least one trench. FIG. 1B illustrates a cross-sectional view corresponding to various embodiments of act 502.

At act 503, an electrically conductive material is filled into the trench to form at least one interconnect. FIGS. 1C-1D illustrate cross-sectional views corresponding to various embodiments of act 503. A thermal conductivity of the one or more interconnects may be larger than a thermal conductivity of a commonly used electrically conductive metal material.

At act 504, a second dielectric layer is formed on the first dielectric layer. FIG. 1E illustrates a cross-sectional view corresponding to various embodiments of act 504. A thermal conductivity of the second dielectric layer may be larger than a thermal conductivity of a commonly used electrically conductive metal material.

At act 505, at least one electrically conductive via penetrating the second dielectric layer is formed to electrically connect to the interconnect. FIGS. 1F-1G illustrate cross-sectional views corresponding to various embodiments of act 505. A thermal conductivity of the one or more electrically conductive vias may be larger than a thermal conductivity of a commonly used electrically conductive metal material.

At act 506, an electronic device disposed on the second dielectric layer and electrically connected to the interconnect through the electrically conductive via is provided. FIGS. 1H, 2, and/or 3 illustrate cross-sectional views corresponding to various embodiments of act 506.

Accordingly, in some embodiments, the present disclosure relates to an electronic component including at least one thermal conductivity dielectric layer and/or at least one electrically and thermally conductive layer thermally coupled to an electronic device within the back-end-of-line (BEOL) structure. The electronic component may have a better heat dissipation.

In accordance with some embodiments of the present disclosure, an electronic device includes a substrate, a first dielectric layer, a plurality of interconnects, a second dielectric layer, a plurality of electrically conductive vias, and an electronic device. The first dielectric layer is disposed on the substrate. The interconnects are disposed on the substrate. The second dielectric layer is disposed on the first dielectric layer. The electrically conductive vias penetrate the second dielectric layer. The electronic device is disposed on the second dielectric layer and electrically connected to at least one of the interconnects through at least one of the electrically conductive vias. A thermal conductivity of the first dielectric layer, a thermal conductivity of the interconnects, a thermal conductivity of the second dielectric layer, or/and a thermal conductivity of the electrically conductive vias are larger than a thermal conductivity of cupper. In an embodiment, the electronic device comprises a passive device. In an embodiment, a top of the interconnect electrically connected to the electronic device has a recess corresponding to a bottom of the electrically conductive via electrically connected thereto. In an embodiment, the electrically conductive via electrically connected to the electronic device is embedded in the interconnect electrically connected thereto. In an embodiment, a material of the interconnects comprises electrically conductive 2D material. In an embodiment, an electrical resistance of the interconnects in directions substantially parallel to a plane is lower than an electrical resistance of the interconnects in another direction substantially perpendicular to the plane. In an embodiment, a material of the electrically conductive vias comprises carbon-based electrically conductive filler. In an embodiment, the electrically conductive via has an extension direction from the electronic device to the interconnect electrically connected thereto, and an electrical resistance of the electrically conductive via in a direction substantially parallel to the extension direction is lower than an electrical resistance of the electrically conductive via in other directions substantially perpendicular to the extension direction. In an embodiment, a top of the interconnect electrically connected to the electronic device has a recess corresponding to a bottom of the electrically conductive via electrically connected thereto, and the electrically conductive via is embedded in the recess of the interconnect.

In accordance with some embodiments of the present disclosure, an electronic device includes a semiconductor substrate, a back-end-of-line (BEOL) structure, and an electronic device. The BEOL structure includes a plurality of patterned electrically conductive layers and a plurality of dielectric layers and is disposed on the semiconductor substrate. The electronic device is within the BEOL structure. The patterned electrically conductive layers include at least one electrically and thermally conductive layer electrically and thermally coupled to the electronic device. The dielectric layers include at least one thermally conductive dielectric layer thermally coupled to the electronic device. In an embodiment, the thermally conductive dielectric layer is at least disposed between the semiconductor substrate and the electronic device. In an embodiment, a thermal conductivity of the electrically and thermally conductive layer, or/and a thermal conductivity of the thermally conductive dielectric layer are larger than a thermal conductivity of cupper. In an embodiment, at least six patterned electrically conductive layers of the BEOL structure are disposed between the semiconductor substrate and the electronic device. In an embodiment, each of the at least six patterned electrically conductive layers comprises corresponding interconnects. In an embodiment, the dielectric layers comprise a first thermally conductive dielectric layer and a second thermally conductive dielectric layer, and the electronic device is disposed between the first thermally conductive dielectric layer and the second thermally conductive dielectric layer. In an embodiment, each of the patterned electrically conductive layers includes corresponding interconnects, and a heat generated by the electronic device is greater than a heat generated by any of the interconnects when the electronic component is operating. In an embodiment, each of the patterned electrically conductive layers includes corresponding interconnects, and an electrical resistance of the electronic device is greater than an electrical resistance of any of the interconnects.

In accordance with some embodiments of the present disclosure, a method includes: providing a structure including a substrate and a first dielectric layer disposed on the substrate; performing a removal process to remove a portion of the first dielectric layer to form at least one trench; filling an electrically conductive material into the trench to form at least one interconnect; forming a second dielectric layer on the first dielectric layer; forming at least one electrically conductive via penetrating the second dielectric layer to electrically connect to the interconnect; and providing an electronic device disposed on the second dielectric layer and electrically connected to the interconnect through the electrically conductive via. A thermal conductivity of the first dielectric layer, a thermal conductivity of interconnects, a thermal conductivity of the second dielectric layer, or/and a thermal conductivity of the electrically conductive vias are larger than a thermal conductivity of cupper. In an embodiment, a deposition process with a process temperature lower than or substantially equal to 450° C. is performed to form the electrically conductive material and/or the electrically conductive via. In an embodiment, a deposition process with a process temperature lower than or substantially equal to 450° C. is performed to form the first dielectric layer and/or the second dielectric layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An electronic component, comprising:
a substrate;
a first dielectric layer, disposed on the substrate;
a plurality of interconnects, disposed on the substrate;
a second dielectric layer, disposed on the first dielectric layer;
a plurality of electrically conductive vias, penetrating the second dielectric layer; and
an electronic device, disposed on the second dielectric layer and electrically connected to at least one of the interconnects through at least one of the electrically conductive vias,
wherein a thermal conductivity of the first dielectric layer, a thermal conductivity of the interconnects, a thermal conductivity of the second dielectric layer, or/and a thermal conductivity of the electrically conductive vias are larger than a thermal conductivity of cupper.

2. The electronic component of claim 1, wherein the electronic device comprises a passive device.

3. The electronic component of claim 1, wherein a top of the interconnect electrically connected to the electronic device has a recess corresponding to a bottom of the electrically conductive via electrically connected thereto.

4. The electronic component of claim 1, wherein the electrically conductive via electrically connected to the electronic device is embedded in the interconnect electrically connected thereto.

5. The electronic component of claim 1, wherein a material of the interconnects comprises electrically conductive 2D material.

6. The electronic component of claim 1, wherein an electrical resistance of the interconnects in directions substantially parallel to a plane is lower than an electrical resistance of the interconnects in another direction substantially perpendicular to the plane.

7. The electronic component of claim 1, wherein a material of the electrically conductive vias comprises carbon-based electrically conductive filler.

8. The electronic component of claim 1,
wherein the electrically conductive via has an extension direction from the electronic device to the interconnect electrically connected thereto, and
wherein an electrical resistance of the electrically conductive via in a direction substantially parallel to the extension direction is lower than an electrical resistance of the electrically conductive via in other directions substantially perpendicular to the extension direction.

9. The electronic component of claim 8, wherein a top of the interconnect electrically connected to the electronic device has a recess corresponding to a bottom of the electrically conductive via electrically connected thereto, and the electrically conductive via is embedded in the recess of the interconnect.

10. An electronic component, comprising:
a semiconductor substrate;
a back-end-of-line (BEOL) structure, comprising a plurality of patterned electrically conductive layers and a plurality of dielectric layers, and disposed on the semiconductor substrate; and
an electronic device, within the BEOL structure,
wherein the patterned electrically conductive layers comprise at least one electrically and thermally conductive layer electrically and thermally coupled to the electronic device, and
wherein the dielectric layers comprise at least one thermally conductive dielectric layer thermally coupled to the electronic device.

11. The electronic component of claim 10, wherein the thermally conductive dielectric layer is at least disposed between the semiconductor substrate and the electronic device.

12. The electronic component of claim 10, wherein a thermal conductivity of the electrically and thermally conductive layer, or/and a thermal conductivity of the thermally conductive dielectric layer are larger than a thermal conductivity of cupper.

13. The electronic component of claim 10, wherein at least six patterned electrically conductive layers of the BEOL structure are disposed between the semiconductor substrate and the electronic device.

14. The electronic component of claim 13, wherein each of the at least six patterned electrically conductive layers comprises corresponding interconnects.

15. The electronic component of claim 10, wherein the dielectric layers comprise a first thermally conductive dielectric layer and a second thermally conductive dielectric layer, and the electronic device is disposed between the first thermally conductive dielectric layer and the second thermally conductive dielectric layer.

16. The electronic component of claim 10, each of the patterned electrically conductive layers comprises corresponding interconnects, and a heat generated by the electronic device is greater than a heat generated by any of the interconnects when the electronic component is operating.

17. The electronic component of claim 10, each of the patterned electrically conductive layers comprises corresponding interconnects, and an electrical resistance of the electronic device is greater than an electrical resistance of any of the interconnects.

18. A method, comprising:
providing a structure including a substrate and a first dielectric layer disposed on the substrate;
performing a removal process to remove a portion of the first dielectric layer to form at least one trench;
filling an electrically conductive material into the trench to form at least one interconnect;
forming a second dielectric layer on the first dielectric layer;
forming at least one electrically conductive via penetrating the second dielectric layer to electrically connect to the interconnect; and
providing an electronic device disposed on the second dielectric layer and electrically connected to the interconnect through the electrically conductive via,
wherein a thermal conductivity of the first dielectric layer, a thermal conductivity of interconnects, a thermal conductivity of the second dielectric layer, or/and a thermal conductivity of the electrically conductive via are larger than a thermal conductivity of cupper.

19. The method of claim 18, wherein a deposition process with a process temperature lower than or substantially equal to 450° C. is performed to form the electrically conductive material and/or the electrically conductive via.

20. The method of claim 18, wherein a deposition process with a process temperature lower than or substantially equal to 450° C. is performed to form the first dielectric layer and/or the second dielectric layer.
